(19) United States
(12) Patent Application Publication
(10) Pub. No.: US 2024/0376341 A1
(43) Pub. Date: Nov. 14, 2024

(54) EPOXY COATING COMPOSITION FOR PROTECTION OF ELECTRONIC CIRCUIT BOARDS AND PREPARATION METHOD THEREOF

(71) Applicants: Hyundai Motor Company, Seoul (KR); Kia Corporation, Seoul (KR); Buhmwoo Institute of Technology Research, Hwaseong, Gyeonggi-do (KR); SNS CO., LTD., Yeoju, Gyeonggi-do (KR)

(72) Inventors: Tae Seung Lee, Suwon (KR); Yong Cheol Kim, Seoul (KR); Chan Kook Chu, Incheon (KR); Chang Soo Yu, Yeoju (KR)

(21) Appl. No.: 18/529,933

(22) Filed: Dec. 5, 2023

(30) Foreign Application Priority Data
May 11, 2023 (KR) 10-2023-0061126

(51) Int. Cl. C09D 163/00; B01J 31/02; C09D 7/20; C09D 7/63; C09D 7/65; H05K 3/28

(52) U.S. Cl. CPC C09D 163/00; B01J 31/0211; C09D 7/20; C09D 7/63; C09D 7/65; H05K 3/28

(57) ABSTRACT

Disclosed are an epoxy coating composition for protection of electronic circuit boards and a preparation method thereof to improve the reliability and durability of the electronic circuit board. The epoxy coating composition includes an amount of about 35 to 70 wt % of a modified epoxy resin including a fatty acid-acrylic epoxy resin, an amount of about 30 to 65 wt % of a first solvent, an amount of about 0.1 to 1.2 wt % of a metal catalyst, an amount of about 0.05 to 0.45 wt % of a defoamer, and an amount of about 0.1 to 0.5 wt % of a surface conditioner, based on the total weight of the epoxy coating composition. The fatty acid-acrylic epoxy resin is prepared by polymerizing a reactant that is obtained by a reaction between an epoxy resin mixture and an unsaturated fatty acid with an acrylic resin using a polymerization catalyst.

### CROSS-REFERENCE TO RELATED APPLICATION

This application claims under 35 U.S.C. § 119 (a) the benefit of priority to Korean Patent Application No. 10-2023-0061126 filed on May 11, 2023, the entire contents of which are incorporated herein by reference.

### TECHNICAL FIELD

The present disclosure relates to an epoxy coating composition for protection of electronic circuit boards and a preparation method thereof.

### BACKGROUND

An electronic circuit board is a board in which various electronic components, such as semiconductor devices, condensers, resistors, capacitors and integrated circuits configured to operate an electrical and electronic product and to control the functions thereof, are mounted in a printed circuit board (PCB) so as to form electronic circuitry.

Various electrical and electronic components mounted on the electronic circuit board include metal materials, for example, copper, silver, gold, lead, tin, and/or brass. These metal materials may be corroded by moisture or corrosive gas. Further, these metal materials may be contaminated by (or come into contact with) foreign substances. Corrosion or contamination of the metal materials in the components mounted in the circuit board may cause shortening of the lifespan or malfunction of the product including the circuit board.

In order to prevent the above problems, protective coating (for example, conformal coating) has been performed, and a protective coating layer may serve as a barrier layer which protects the entirety or a part of the electrical and electronic components depending on the degree of integration of the electrical and electronic components and the circuit configuration thereof.

Materials for such a conformal coating composition conventionally include silicon resins, olefin resins (or rubber resins), acrylic resins, polyurethane resins, epoxy resins, modified alkyd resins, and the like, and require ease of uniform application, formation of a protective coating film having a uniform thickness when dried and cured, excellent electrical insulation, low moisture permeability, adhesion on the electronic circuit board and components and circuits mounted thereon, as basic properties, and may further require flexibility depending on a component and a board to which the materials are applied.

Further, the materials should secure reliability of the electrical and electronic components despite various external environmental changes, such as high-temperature and high-humidity, sudden temperature changes, vibration, and the like, for a long period of use of the electronic circuit board.

Moreover, the conformal coating composition for electronic circuit boards requires a one-component type liquid formulation, the viscosity of which is little changed, so as to be continuously used in a manufacturing process or to continue to be used even in a rest period.

In the related art, development of a coating composition for electronic circuit boards, which may be easily applied to a conventional coating operation and the coating lines of an automated continuous process, may have low odor emission, may be a one-component type to be uniformly applied to an electronic circuit board, and may form a transparent film through drying at room temperature and oxidative curing, so as to protect the electronic circuit board from external environmental changes, such as temperature, humidity, moisture and vibration, and foreign substances, such as dust and contaminants, is required.

The above information disclosed in this Background section is only for enhancement of understanding of the background of the invention and therefore it may contain information that does not form the prior art that is already known in this country to a person of ordinary skill in the art.

### SUMMARY

In preferred aspects, provided is an epoxy coating composition for protection of electronic circuit boards, which may protect an electronic circuit board from external environmental changes, such as temperature, humidity, moisture and vibration, and foreign substances, such as dust and contaminants, and a method of preparation thereof.

In one aspect, provided is an epoxy coating composition for protection of electronic circuit boards, and the epoxy coating composition includes an amount of about 35 to 70 wt % of a modified epoxy resin including a fatty acid-acrylic epoxy resin, an amount of about 30 to 65 wt % of a first solvent, an amount of about 0.1 to 1.2 wt % of a metal catalyst, an amount of about 0.05 to 0.45 wt % of a defoamer, and an amount of about 0.1 to 0.5 wt % of a surface conditioner, based on the total weight of the epoxy coating composition. The fatty acid-acrylic epoxy resin is prepared by polymerizing a reactant that is obtained by a reaction between an epoxy resin mixture and an unsaturated fatty acid with an acrylic resin. In certain embodiments, suitably, a polymerization catalyst may be used in the reaction to prepare that reactant that is used to prepare the fatty acid-acrylic epoxy resin.

The reactant may be obtained by a dehydration condensation reaction between 100 parts by weight of the epoxy resin mixture and about 50 to 80 parts by weight of the unsaturated fatty acid.

The epoxy resin mixture may include, based on a total weight of the epoxy resin mixture, an amount of about 60 to 80 wt % of a first epoxy resin and an amount of about 20 to 40 wt % of a second epoxy resin. The first epoxy resin may have a softening point of about 60 to 85° C., and the second epoxy resin may have a softening point of about 110 to 140° C.

The unsaturated fatty acid may include one or more selected from the group consisting of a castor oil-derived fatty acid, a soybean oil-derived fatty acid, and a rapeseed oil-derived fatty acid, and the unsaturated fatty acid may have an iodine value of about 100 to 150 mgKOH/g.

The fatty acid-acrylic epoxy resin may be obtained by a reaction between 100 parts by weight of the reactant and about 10 to 30 parts by weight of the acrylic resin.

The polymerization catalyst may suitably include bis(1,1-dimethyl) peroxide (di-tert-butyl peroxide).

The acrylic resin may include one or more selected from the group consisting of methyl methacrylate, methyl acrylate, ethyl acrylate, and ethylhexyl acrylate.

The modified epoxy resin may further include a second solvent including an alcohol glycol ether-based solvent, a ketone-based solvent, or a combination thereof.

The alcohol glycol ether-based solvent may include one or more selected from the group consisting of butyl carbitol, propylene glycol monomethyl ether, and propylene glycol monoethyl ether, and the ketone-based solvent may include one or more selected from the group consisting of methyl ethyl ketone, methyl isobutyl ketone, acetone, and dimethyl carbonate.

The modified epoxy resin may have a Gardner viscosity of Z to Z2, an acid value of less than about 8 mgKOH/g, an iodine value of about 20 to 50 mgKOH/g, and a solids content of about 30 to 70 wt % based on the total weight of the modified epoxy resin.

The first solvent may include, with respect to 100 wt % of the epoxy coating composition, an amount of about 30 to 60 wt % of a ketone-based solvent and an amount of about 0 to 5 wt % of a carbon-based solvent.

The ketone-based solvent may include one or more selected from the group consisting of methyl ethyl ketone, methyl isobutyl ketone, acetone, and dimethyl carbonate, and the carbon-based solvent may include naphthene-based hydrocarbon, paraffin-based hydrocarbon, or a combination thereof.

The metal catalyst may include one or more selected from the group consisting of cobalt octoate, calcium octoate, and zirconium octoate.

The defoamer may include a silicone-based defoamer, a silicone-free defoamer, or a combination thereof, the silicone-based defoamer may include one or more selected from the group consisting of polydimethylsiloxane, polyether-modified polydimethylsiloxane, and fluorine-modified polydimethylsiloxane, and the silicone-free defoamer may include polyacrylates, polyalkylene ethers, or combinations thereof.

The surface conditioner may include a polyacrylate-based surface conditioner, a polyalkylene ether-based surface conditioner, and a combination thereof.

The epoxy coating composition may further include an amount of about 0.01 to 0.1 wt % of a fluorescent agent based on the total weight of the epoxy coating composition.

In another aspect, provided is an electronic circuit board including a board, and a coating layer located on the board and including an epoxy coating composition. The epoxy coating composition includes an amount of about 35 to 70 wt % of a modified epoxy resin including a fatty acid-acrylic epoxy resin, an amount of about 30 to 65 wt % of a first solvent, an amount of about 0.1 to 1.2 wt % of a metal catalyst, an amount of about 0.05 to 0.45 wt % of a defoamer, and an amount of about 0.1 to 0.5 wt % of a surface conditioner, based on the total weight of the epoxy coating composition. The fatty acid-acrylic epoxy resin is prepared by polymerizing a reactant that is obtained by a reaction between an epoxy resin mixture and an unsaturated fatty acid with an acrylic resin using a polymerization catalyst.

In another aspect, provided is a method of preparing an epoxy coating composition for protection of electronic circuit boards. The method includes steps of preparing a reactant obtained by a dehydration condensation reaction between an epoxy resin mixture and a unsaturated fatty acid, preparing a fatty acid-acrylic modified epoxy resin by polymerizing the reactant with an acrylic resin using a polymerization catalyst, preparing a modified epoxy resin by diluting the fatty acid-acrylic modified epoxy resin with a second solvent, and reacting an amount of about 35 to 70 wt % of the modified epoxy resin, an amount of about 30 to 65 wt % of a first solvent, an amount of about 0.1 to 1.2 wt % of a metal catalyst, an amount of about 0.05 to 0.45 wt % of a defoamer, and an amount of about 0.1 to 0.5 wt % of a surface conditioner, based on the total weight of the epoxy coating composition, and then stirring the same.

The fatty acid-acrylic epoxy resin may be obtained by a reaction between 100 parts by weight of the reactant and about 10 to 30 parts by weight of the acrylic resin. The reactant may be obtained by a dehydration condensation reaction between 100 parts by weight of the epoxy resin mixture and about 50 to 80 parts by weight of the unsaturated fatty acid.

The fatty acid-acrylic epoxy resin may include a first epoxy resin having a softening point of about 60 to 85° C. and a second epoxy resin having a softening point of about 110 to 140° C., the unsaturated fatty acid may include one or more selected from the group consisting of a castor oil-derived fatty acid, a soybean oil-derived fatty acid, and a rapeseed oil-derived fatty acid, the acrylic resin may include one or more selected from the group consisting of methyl methacrylate, methyl acrylate, ethyl acrylate, and ethylhexyl acrylate, the polymerization catalyst may include bis(1,1-dimethyl) peroxide (di-tert-butyl peroxide), the first solvent may include a ketone-based solvent, a carbon-based solvent, or a combination thereof, and the second solvent may include an alcohol glycol ether-based solvent, a ketone-based solvent, or a combination thereof.

Also provided is a vehicle part including the electronic circuit board as described herein.

Other aspects and preferred embodiments of the invention are discussed infra.

### DETAILED DESCRIPTION

The above-described objects, other objects, advantages and features of the present invention will become apparent from the descriptions of embodiments given hereinbelow with reference to the accompanying drawings. However, the present invention is not limited to the embodiments disclosed herein and may be implemented in various different forms. The embodiments are provided to make the description of the present invention thorough and to fully convey the scope of the present invention to those skilled in the art.

In the following description of the embodiments, terms, such as “including”, “comprising” and “having”, are to be interpreted as indicating the presence of characteristics, numbers, steps, operations, elements or parts stated in the description or combinations thereof, and do not exclude the presence of one or more other characteristics, numbers, steps, operations, elements, parts or combinations thereof, or possibility of adding the same.

All numbers, values and/or expressions representing amounts of components, reaction conditions, polymer compositions and blends used in the description are approximations in which various uncertainties in measurement generated when these values are obtained from essentially different things are reflected and thus it will be understood that they are modified by the term “about”, unless stated otherwise. Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

In addition, it will be understood that, if a numerical range is disclosed in the description, such a range includes all continuous values from a minimum value to a maximum value of the range, unless stated otherwise. Further, if such a range refers to integers, the range includes all integers from a minimum integer to a maximum integer, unless stated otherwise.

In the following description of the embodiments, it will be understood that, when the range of a variable is stated, the variable includes all values within the stated range including stated end points of the range. For example, it will be understood that a range of “5 to 10” includes not only values of 5, 6, 7, 8, 9 and 10 but also arbitrary subranges, such as a subrange of 6 to 10, a subrange of 7 to 10, a subrange of 6 to 9, and a subrange of 7 to 9, and arbitrary values between integers which are valid within the scope of the stated range, such as 5.5, 6.5, 7.5, 5.5 to 8.5, and 6.5 to 9. Further, for example, it will be understood that a range of “10% to 30%” includes not only all integers including values of 10%, 11%, 12%, 13%, . . . 30% but also arbitrary subranges, such as a subrange of 10% to 15%, a subrange of 12% to 18%, and a subrange of 20% to 30%, and arbitrary values between integers which are valid within the scope of the stated range, such as 10.5%, 15.5%, and 25.5%.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles. In certain preferred aspects, a vehicle may be electric-powered, including a hybrid vehicles, plug-in hybrids, or vehicles where electric power is the primary or sole power source.

An epoxy coating composition for protection of electronic circuit boards includes an amount of about 35 to 70 wt % of a modified epoxy resin including a fatty acid-acrylic epoxy resin, an amount of about 30 to 65 wt % of a first solvent, an amount of about 0.1 to 1.2 wt % of a metal catalyst, an amount of about 0.05 to 0.45 wt % of a defoamer, and an amount of about 0.1 to 0.5 wt % of a surface conditioner, based on the total weight of the epoxy coating composition. The fatty acid-acrylic epoxy resin is formed by polymerizing a first resin, which is obtained by a dehydration condensation reaction between an epoxy resin mixture and an unsaturated fatty acid with an acrylic resin using a polymerization catalyst.

Respective components of the epoxy coating composition according to the present invention will be described in more detail as follows.

### (A) Modified Epoxy Resin

The modified epoxy resin is obtained by adding a second solvent, which is a dilute solvent, to the fatty acid-acrylic epoxy resin. The content of the modified epoxy resin may be about 35 to 70 wt % with respect to 100 wt % of the epoxy coating composition.

The second solvent may include an alcohol glycol ether-based solvent, a ketone-based solvent, or a combination thereof.

The alcohol glycol ether-based solvent may secure a temperature equal to or higher than a reaction temperature at which fatty acid-acryl polymerization of the first resin, i.e., a reactant, may occur, and to improve the drying speed of the epoxy coating composition.

The alcohol glycol ether-based solvent may include one or more selected from the group consisting of butyl carbitol, propylene glycol monomethyl ether, and propylene glycol monoethyl ether. The alcohol glycol ether-based solvent may preferably include propylene glycol monomethyl ether which has volatility and a relatively low boiling point.

Further, as a dilute solvent which secures viscosity based on compatibility among the reacting components and ease of working when the modified epoxy resin is prepared, the ketone-based solvent, which is a polar solvent, may preferably be used.

The ketone-based solvent may include one or more selected from the group consisting of methyl ethyl ketone, methyl isobutyl ketone, acetone, and dimethyl carbonate.

In order to secure the proper drying speed of the epoxy coating composition during operation, the ketone-based solvent may preferably be dimethyl carbonate.

The modified epoxy resin may have a Gardner viscosity of Z to Z2, an acid value of less than about 8 mgKOH/g, an iodine value of about 20 to 50 mgKOH/g, and a solids content of about 30 to 70 wt %, based on the total weigh of the modified epoxy resin, due to the second solvent which is a dilute solvent. The modified epoxy resin may preferably have an acid value of less than about 6 mgKOH/g, an iodine value of about 30 to 40 mgKOH/g, and a solids content of about 40 to 50 wt %, based on the total weigh of the modified epoxy resin.

When the solids content of the modified epoxy resin is less than about 30 wt %, it is difficult to secure a film thickness at a part having a complicated shape on an electronic circuit board, for example, a vertical part of a lead of an IC chip, in applying the epoxy coating composition to a product. On the other and, when the solids content of the modified epoxy resin is greater than about 70 wt %, the viscosity of the coating composition is high, and thus, it may be difficult to defoam the coating composition during a coating operation, and appearance defects, such as wrinkles, may occur due to poor leveling. Therefore, as the solids content increases, the storage stability of the epoxy coating composition becomes poor.

The modified epoxy resin includes the fatty acid-acrylic epoxy resin. The fatty acid-acrylic epoxy resin will be described in more detail as follows.

The fatty acid-acrylic epoxy resin is obtained by polymerizing the reactant, obtained by the reaction between the epoxy resin mixture and the unsaturated fatty acid, with the acrylic resin using the polymerization catalyst.

### (A-1) Reactant

The reactant is obtained by the reaction between the epoxy resin mixture and the unsaturated fatty acid.

The reactant may be obtained by the dehydration condensation reaction of the unsaturated fatty acid with the epoxy resin mixture including one or more epoxy resins having different softening points. The reactant may be obtained by the dehydration condensation reaction between the epoxy resin mixture and the unsaturated fatty acid, e.g., after mixing about 50 to 80 parts by weight of the unsaturated fatty acid with 100 parts by weight of the epoxy resin mixture. When the content of the unsaturated fatty acid is less than about 50 parts by weight with respect to 100 parts by weight of the epoxy resin mixture, the density of a coating film is poor and thus insulation resistance of a product is poor in a high-temperature and high-humidity, and the hardness of the coating film is increased and thus it is difficult to secure flexural properties, in applying the epoxy coating composition to a product. On the other hand, when the content of the unsaturated fatty acid is greater than about 80 parts by weight, the flexibility of the coating film is increased and thus it is easy to secure flexural properties, but drying and curing of the epoxy coating composition are slow and thus workability is poor during working operation and stickiness of the coating film may cause contamination by foreign substances.

The epoxy resin mixture may include a first epoxy resin and a second epoxy resin. The first epoxy resin and the second epoxy resin may be bisphenol A which is generally and widely used, and may have softening points which are in the range of about 60 to 150° C.

Preferably, it is advantageous to mix an epoxy resin having a low softening point and an epoxy resin having a high softening point in view ease of preparation of the epoxy coating composition, storage stability of the epoxy coating composition, and flexural properties of the coating film.

More preferably, the epoxy resin mixture includes a first epoxy resin having a low softening point which is in the range of about 60 to 85° C., and a second epoxy resin having a high softening point which is in the range of about 110 to 140° C.

The epoxy resin mixture may include an amount of about 60 to 80 wt % of the first epoxy resin, and an amount of about 20 to 40 wt % of the second epoxy resin, based on the total weight of the epoxy resin mixture.

In the present invention, the unsaturated fatty acid is used to enable curing at room temperature through an oxidative curing mechanism, and to introduce an acrylic resin polymerization functional group so as to improve the properties of the coating film.

The unsaturated fatty acid may include one or more selected from the group consisting of a castor oil-derived fatty acid, a soybean oil-derived fatty acid, and a rapeseed oil-derived fatty acid.

The unsaturated fatty acid may include a fatty acid, which is in the range of C16 to C22, as a main component, and the unsaturation of the unsaturated fatty acid may be an iodine value of about 100 to 150 mgKOH/g.

### (A-2) Acrylic Resin

First, the fatty acid-acrylic epoxy resin may be obtained by a reaction between the reactant and the acrylic resin, e.g., after mixing about 10 to 30 parts by weight of the acrylic resin with 100 parts by weight of the reactant. When the content of the acrylic resin is less than about 10 parts by weight, a degree of polymerization is small, and thus, the density of the coating film is low and the electrical characteristics of the coating film are poor in a high-temperature and high-humidity environment, in applying the epoxy coating composition to a final product. On the other hand, when the content of the acrylic resin is greater than about 30 parts by weight, the hardness of the coating film is increased and thus it is difficult to secure flexural properties, in applying the epoxy coating composition to a final product.

The acrylic resin may include at least one selected from the group consisting of methyl methacrylate, methyl acrylate, ethyl acrylate, ethylhexyl acrylate, and combinations thereof.

### (A-3) Polymerization Catalyst

The polymerization catalyst may include bis(1,1-dimethyl) peroxide (di-tert-butyl peroxide).

### (B) First Solvent

The first solvent may include at least one selected from the group consisting of a ketone-based solvent, a carbon-based solvent, and a combination thereof. The content of the first solvent may be about 30 to 65 wt % with respect to 100 wt % of the epoxy coating composition.

The first solvent may preferably use a polar solvent for the purpose of dilution so as to secure compatibility among the components, storage stability of the epoxy coating composition, ease of working thereof, and a proper viscosity depending on an application method and application conditions of the epoxy coating composition.

Particularly, the epoxy coating composition may use the ketone-based solvent as the polar solvent so as to secure a low viscosity depending on an application method and application conditions of the epoxy coating composition, and the content of the ketone-based solvent may be about 30 to 60 wt % with respect to 100 wt % of the epoxy coating composition.

The first solvent may use the same ketone-based solvent as the ketone-based solvent used in preparation of the modified epoxy resin, as a diluent.

The ketone-based solvent may include one or more selected from the group consisting of methyl ethyl ketone, methyl isobutyl ketone, acetone, and dimethyl carbonate.

Further, the epoxy coating composition may use the carbon-based solvent, which is a nonpolar solvent, as an additional dilute solvent configured to adjust the drying speed depending on increase in a solvent amount, and to improve leveling of the coating film.

Preferably, less than about 5 wt % of the carbon-based solvent may be used with respect to 100 wt % of the epoxy coating composition. More preferably, about 3 wt % or less of the carbon-based solvent may be used with respect to 100 wt % of the epoxy coating composition. When about 5 wt % or greater of the carbon-based solvent is used in the epoxy coating composition, the drying and curing speed may be poor, the epoxy coating composition may be sticky and undried due to the remaining the carbon-based solvent, and thereby, performance of the epoxy coating composition may be deteriorated.

The carbon-based solvent may include naphthene-based hydrocarbons, paraffin-based hydrocarbons, or combinations thereof.

The carbon-based solvent may include at least one selected from the group consisting of C7 to C12 naphthene-based solvents and C8 to C13 paraffin-based solvents, and combinations thereof. The carbon-based solvent may have a flash point of about-10 to 60° C., and a distillation range of about 85 to 190° C.

Preferably, in consideration of working environments, such as the drying speed and odor emission of the composition, the C7 to C12 naphthene-based solvents and the C8 to C13 paraffin-based solvents may preferably be used as the carbon-based solvent.

### (C) Metal Catalyst

The metal catalyst breaks double bonds in the modified epoxy resin in the epoxy coating composition, and synthesizes a polymer through a reaction with oxygen in the air.

The content of the metal catalyst may be about 0.1 to 1.2 wt % with respect to 100 wt % of the epoxy coating composition.

The metal catalyst may include one or more selected from the group consisting of cobalt octoate, calcium octoate, and zirconium octoate.

The metal catalyst may include a first metal catalyst and a second metal catalyst depending on a curing speed and a curing mechanism. In the present invention, the first metal catalyst and the second metal catalyst may be mixed and used as the metal catalyst.

The first metal catalyst may include cobalt octoate, cobalt naphthenate, manganese octoate, cerium octoate, or the like. The first metal catalyst may include an oxidative dryer in view of the curing mechanism thereof, and is advantageous in that it increases a curing speed. On the other hand, in the case in which the first metal catalyst is used alone, the surface of the coating film contacting oxygen is rapidly dried, the dried film causes difficulty in diffusing oxygen to the inside of the coating film and thus causes slow curing of the inside of the coating film, and thereby, appearance defects, such as a striped pattern, may occur. Further, the first metal catalyst may deteriorate adhesiveness of the coating film to an object to be adhered.

The second metal catalyst may include lead octoate, barium octoate, zirconium octoate, or the like. The second metal catalyst generally is a polymerizable dryer in view of the curing mechanism thereof, and the second metal catalyst has a low oxidation rate compared to the first metal catalyst, but uniformly acts on the surface and the inside of the coating film and may thus form a uniformly dried and cured coating film.

### (D) Defoamer

The defoamer facilitates reduction of formation of foam bubbles or removal of the foam bubbles, and the content of the defoamer may be about 0.05 to 0.45 wt % with respect to 100 wt % of the epoxy coating composition.

The defoamer may include a silicone-based defoamer, a silicone-free defoamer, or a combination thereof.

The silicone-based defoamer may include one or more selected from the group consisting of polydimethylsiloxane, polyether-modified polydimethylsiloxane, and fluorine-modified polydimethylsiloxane.

The silicone-free defoamer may include polyacrylates, polyalkylene ethers, or combinations thereof.

### (E) Surface Conditioner

The surface conditioner adjusts surface tension to improve appearance quality, and the content of the surface conditioner may be about 0.1 to 0.5 wt % with respect to 100 wt % of the epoxy coating composition.

When the content of the surface conditioner is less than about 0.1 wt %, a quality improvement effect of the epoxy coating composition may be small, and, when the content of the surface conditioner is greater than about 0.5 wt %, the quality of the epoxy coating composition may be deteriorated due to use of an excessive amount of the surface conditioner.

The surface conditioner may include at least one selected from the group consisting of a polyacrylate-based surface conditioner, a polyalkylene ether-based surface conditioner, and a combination thereof.

### (F) Fluorescent Agent

A fluorescent agent may be used to check an applied area and an applied state, and the content of the fluorescent agent may be about 0.01 to 0.1 wt % with respect to 100 wt % of the epoxy coating composition.

In another aspect, the present invention relates to an electronic circuit board including an epoxy coating composition. In particular, th components of the epoxy coating composition in the electronic circuit board are the same as those of the above-described epoxy coating composition, and a detailed description thereof will thus be omitted.

The electronic circuit board includes a board, and a coating layer located on the board and including the above epoxy coating composition.

The coating layer may be formed by applying the epoxy coating composition to the board and curing the applied epoxy coating composition by natural drying or hot air. For example, electronic components mounted on the electronic circuit board may be protected from external environmental changes, such as temperature, humidity, moisture and vibration, and foreign substances, such as dust and contaminants, by the coating layer including the epoxy coating composition located on the board.

The epoxy coating composition includes an amount of about 35 to 70 wt % of a modified epoxy resin including a fatty acid-acrylic epoxy resin, an amount of about 30 to 65 wt % of a first solvent, an amount of about 0.1 to 1.2 wt % of a metal catalyst, an amount of about 0.05 to 0.45 wt % of a defoamer, and an amount of about 0.1 to 0.5 wt % of a surface conditioner, based on the total weight of the epoxy coating composition. Particularly, the fatty acid-acrylic epoxy resin is obtained by polymerizing a first resin that is obtained by a dehydration condensation reaction between an epoxy resin mixture and an unsaturated fatty acid with an acrylic resin using a polymerization catalyst.

In another aspect, provided is a method of manufacturing an epoxy coating composition for protection of electronic circuit boards.

The method of preparing the epoxy coating composition includes steps of preparing a reactant preparing by a dehydration condensation reaction between an epoxy resin mixture and an unsaturated fatty acid, preparing a fatty acid-acrylic modified epoxy resin by polymerizing the reactant with an acrylic resin using a polymerization catalyst, preparing a modified epoxy resin by diluting the fatty acid-acrylic modified epoxy resin with a second solvent, and reacting, e.g., by mixing an amount of about 35 to 70 wt % of the modified epoxy resin, an amount of about 30 to 65 wt % of a first solvent, an amount of about 0.1 to 1.2 wt % of a metal catalyst, an amount of about 0.05 to 0.45 wt % of a defoamer, and an amount of about 0.1 to 0.5 wt % of a surface conditioner, based on the total weight of the epoxy coating composition, and then stirring the same. Hereinafter, the respective operations of the preparation method of the epoxy coating composition according to the present invention will be described in detail.

Prior to the description of the respective operations, the respective components of the epoxy coating composition are the same as those of the above-described epoxy coating composition, and a detailed description thereof will thus be omitted.

First, in the preparation of the reactant, the reactant is prepared by the dehydration condensation reaction between the epoxy resin mixture and the unsaturated fatty acid. The reactant may be obtained by the dehydration condensation reaction between the epoxy resin mixture and the unsaturated fatty acid, e.g., by mixing about 50 to 80 parts by weight of the unsaturated fatty acid with 100 parts by weight of the epoxy resin mixture.

The dehydration condensation reaction may be performed through a stirring process in a nitrogen atmosphere at a temperature of about 200 to 230° C. for about 2 to 3 hours.

The epoxy resin mixture may include a first epoxy resin having a softening point of about 60 to 85° C., and a second epoxy resin having a softening point of about 110 to 140° C.

The unsaturated fatty acid may include at least one selected from the group consisting of a castor oil-derived fatty acid, a soybean oil-derived fatty acid, and a rapeseed oil-derived fatty acid.

Thereafter, in the preparation of the fatty acid-acrylic modified epoxy resin, the fatty acid-acrylic modified epoxy resin is prepared by polymerizing the prepared reactant with the acrylic resin using the polymerization catalyst.

The fatty acid-acrylic epoxy resin may be obtained by a reaction between the reactant and the acrylic resin through the polymerization catalyst, e.g., after mixing about 10 to 30 parts by weight of the acrylic resin with 100 parts by weight of the reactant.

In the preparation of the fatty acid-acrylic modified epoxy resin, the fatty acid-acrylic modified epoxy resin may be obtained by cooling the reactant to a temperature of about 135 to 140° C., and then polymerizing acrylic monomers with double bonds in the fatty acid in the reactant (the fatty acid modified epoxy) in-situ.

The polymerization reaction may be performed through a stirring process at a temperature of about 135 to 140° C. for about 1 to 3 hours.

The acrylic resin may include one or more selected from the group consisting of methyl methacrylate, methyl acrylate, ethyl acrylate, and ethylhexyl acrylate.

The polymerization catalyst may suitably include bis(1,1-dimethyl) peroxide (di-tert-butyl peroxide).

Thereafter, in the preparation of the modified epoxy resin, the modified epoxy resin is prepared by diluting the prepared fatty acid-acrylic modified epoxy resin with the second solvent. Such a dilution process may be performed through a stirring process for about 30 to 90 minutes.

Here, the second solvent may include an alcohol glycol ether-based solvent, a ketone-based solvent, or a combination thereof.

Finally, in the mixing of the respective components of the epoxy coating composition, the epoxy coating composition, which is an end product, is prepared by mixing the prepared modified epoxy resin, the first solvent, the metal catalyst, the defoamer, and the surface conditioner, and then stirring the same.

The stirring process may be performed in a nitrogen atmosphere at a temperature of about 20 to 30° C. for about 20 to 60 minutes.

In the mixing of the respective components of the epoxy coating composition, a mixture of an amount of about 35 to 70 wt % of the modified epoxy resin, an amount of about 30 to 65 wt % of the first solvent, an amount of about 0.1 to 1.2 wt % of the metal catalyst, an amount of about 0.05 to 0.45 wt % of the defoamer, and an amount of about 0.1 to 0.5 wt % of the surface conditioner, based on the total weight of the epoxy coating composition, may be stirred. The first solvent may include at least one selected from the group consisting of a ketone-based solvent, a carbon-based solvent, and a combination thereof.

### EXAMPLE

Hereinafter, the present invention will be described in more detail through the following examples. The following examples serve merely to exemplarily describe the present invention, and are not intended to limit the scope of the invention.

### Manufacturing Examples 1-4

Modified epoxy resins including components having contents set forth in Table 1 below were prepared through a general synthesis method.

Hereinafter, a method of synthesizing the modified epoxy resins will be described in detail.

### Manufacturing Example 1

1). First, a 1 L 4-neck flask was fitted with a thermometer, a condenser, a stirrer, and a moisture removal condenser, and a heating device was attached the flask. A reactant were produced by sequentially putting 79.0 g of a low softening point epoxy resin, 38.0 g of a high softening point epoxy resin, and 81.0 g of a soybean oil-derived fatty acid into the flask, and heating the mixture thereof to a temperature of 220° C. while injecting nitrogen into the flask and stirring the mixture for 2 to 3 hours.
2). When the acid value of the reactant obtained through a process inspection was 5 mgKOH/g or less, the reactant was cooled to a temperature of 135-140° C., and 62.0 g of methyl methacrylate, and 29.5 g of methyl acrylate, 14.0 g of ethylhexyl acrylate, and a polymerization catalyst (di-tert-butyl peroxide) were slowly added dropwise to the reactant for 2 hours, and the reaction was additionally performed for 1 hour, while maintaining a temperature of 135° C. Subsequently, 7.5 g of propylene glycol monomethyl ether and 1.5 g of the polymerization catalyst (di-tert-butyl peroxide) were added dropwise to the reactant for 5 minutes, the reactant was stirred for 2 hours, and the reaction was terminated, thereby preparing a fatty acid-acrylic modified epoxy resin. Here, when the reaction was completed, heating was stopped.
3). A modified epoxy resin having a solids content of 60% and a Gardner viscosity of Z was obtained by sequentially adding 123 g of propylene glycol monomethyl ether and 62.5 g of dimethyl carbonate, as a dilute solvent, into the fatty acid-acrylic modified epoxy resin, and then stirring the mixture thereof for 1 hour.

### Manufacturing Example 2

A modified epoxy resin was prepared in the same manner as in Manufacturing Example 1 except that 94.8 g of the low softening point epoxy resin, 45.6 g of the high softening point epoxy resin, and 70.6 g of the soybean oil-derived fatty acid were used, and 53.3 g of methyl methacrylate, 25.4 g of methyl acrylate, and 12.04 g of ethylhexyl acrylate were used.

The modified epoxy resin obtained by Manufacturing Example 2 had a solids content of 59.5% and a Gardner viscosity of Z1.

### Manufacturing Example 3

A modified epoxy resin was prepared in the same manner as in Manufacturing Example 1 except that 73.9 g of the low softening point epoxy resin, 35.5 g of the high softening point epoxy resin, and 75.7 g of the soybean oil-derived fatty acid were used, 74.4 g of methyl methacrylate, 35.4 g of methyl acrylate, 16.8 g of ethylhexyl acrylate, and 5 g of the polymerization catalyst (di-tert-butyl peroxide) were slowly added dropwise to the reactant for 2 hours, and the reaction was additionally performed for 1 hour.

The modified epoxy resin obtained by Manufacturing Example 3 had a solids content of 61.4% and a Gardner viscosity of Z1 to Z2.

### Manufacturing Example 4

A modified epoxy resin was prepared in the same manner as in Manufacturing Example 1 except that 71.1 g of the low softening point epoxy resin, 34.2 g of the high softening point epoxy resin, and 97.2 g of the soybean oil-derived fatty acid were sequentially put into the flask, the mixture thereof was heated to a temperature of 220° C. while injecting nitrogen thereinto and was stirred 3 to 4 hours, and 55.8 g of methyl methacrylate, 26.6 g of methyl acrylate, 12.6 g of ethylhexyl acrylate were used.

The modified epoxy resin obtained by Manufacturing Example 4 had a solids content of 60% and a Gardner viscosity of Y.

TABLE 1

| | Modified epoxy resin | | | |
|---|---|---|---|---|
| Component | A (Manufacturing | B (Manufacturing | C (Manufacturing | D (Manufacturing |
| (wt %) | example 1) | example 2) | example 3) | example 4) |
| Low softening | 79.0 | 94.8 | 73.4 | 71.1 |
| point epoxy | | | | |
| resin | | | | |
| High softening | 38.0 | 45.6 | 35.5 | 34.2 |
| point epoxy | | | | |
| resin having | | | | |
| Soybean-derived | 81.0 | 70.6 | 75.7 | 97.2 |
| fatty acid | | | | |
| Methyl | 62.0 | 53.3 | 74.4 | 55.8 |
| methacrylate | | | | |
| Methyl acrylate | 29.5 | 25.4 | 35.4 | 26.6 |
| Ethylhexyl | 14.0 | 12.0 | 16.8 | 12.6 |
| acrylate | | | | |
| Polymerization | 3.75 | 3.75 | 3.75 | 3.75 |
| catalyst | | | | |
| Propylene | 130.5 | 130.5 | 130.5 | 130.5 |
| glycol | | | | |
| monomethyl | | | | |
| ether | | | | |
| Dimethyl | 62.5 | 62.5 | 62.5 | 62.5 |
| carbonate | | | | |
| Sum total | 500.25 | 498.47 | 508.42 | 494.2 |

[Components]
Epoxy resin
low softening point epoxy resin: softening point of 70° C.
high softening point epoxy resin: softening point of 121° C.
Unsaturated fatty acid
soybean-derived fatty acid: CAS No. 68308-53-2
Acrylic resin
methyl methacrylate: CAS No. 80-62-6
methyl acrylate: CAS No. 96-33-3
ethylhexyl acrylate: 2-ethylhexyl acrylate, CAS No. 103-11-7
Polymerization catalyst: bis(1,1-dimethyl) peroxide (di-tert-butyl peroxide), CAS No. 110-5-4
Alcohol glycol ether-based solvent
propylene glycol monomethyl ether, CAS No. 107-98-2
Ketone-based solvent
dimethyl carbonate, CAS No. 616-38-6

### Examples

Epoxy coating compositions having components in contents set forth in Table 2 below were prepared using the modified epoxy resins obtained by Manufacturing Examples through a general synthesis method.

Hereinafter, a method of synthesizing each of the epoxy coating compositions will be described in detail.
1). First, a jacket-type SUS reaction vessel, which is capable of adjusting temperature was fitted with a thermometer, a stirrer, and a nitrogen gas line. A primary mixture was manufactured by putting the modified epoxy resin, a solvent, and a surface conditioner into the reaction vessel, and stirring the same for 30 minutes while supplying nitrogen gas and maintaining a temperature of 20 to 30° C.
2). A secondary mixture was manufactured by putting a first metal catalyst and a second metal catalyst into the primary mixture and stirring the same for 1 hour.
3). A tertiary mixture was manufactured by putting a defoamer into the second mixture and additionally stirring the same for 1 hour.
4). An epoxy coating composition was prepared by stopping stirring of the tertiary mixture and aging the tertiary mixture at room temperature for 24 hours or more.

TABLE 2

| Component | | Example | | | | | Comparative example | | | | |
|---|---|---|---|---|---|---|---|---|---|---|---|
| (wt %) | | 1 | 2 | 3 | 4 | 5 | 1 | 2 | 3 | 4 | 5 |
| Modified | A | 60.31 | 60.3 | 69.97 | 45.5 | 45.5 | 0 | 0 | 0 | 60.31 | 60.31 |
| epoxy | B | 0 | 0 | 0 | 0 | 0 | 60.31 | 0 | 0 | 0 | 0 |
| resin | C | 0 | 0 | 0 | 0 | 0 | 0 | 60.31 | 0 | 0 | 0 |
| | D | 0 | 0 | 0 | 0 | 0 | 0 | 0 | 60.31 | 0 | 0 |

| | | | | | | | | | | |
|---|---|---|---|---|---|---|---|---|---|---|
| Ketone-based | 36.46 | 38.4 | 26.8 | 51.9 | 46.7 | 36.46 | 36.46 | 36.46 | 35.66 | 21.4 |
| solvent | | | | | | | | | | |
| Carbon-based | 0 | 0 | 0 | 0 | 5.2 | 0 | 0 | 0 | 0 | 15 |
| solvent | | | | | | | | | | |
| First metal | 0.64 | 0.16 | 0.64 | 0.48 | 0.48 | 0.64 | 0.64 | 0.64 | 0.84 | 0.64 |
| catalyst | | | | | | | | | | |
| Second metal | 1.93 | 0.48 | 1.93 | 1.46 | 1.46 | 1.93 | 1.93 | 1.93 | 2.56 | 1.93 |
| catalyst | | | | | | | | | | |
| Defoamer | 0.16 | 0.16 | 0.16 | 0.16 | 0.16 | 0.16 | 0.16 | 0.16 | 0.15 | 0.16 |
| Surface | 0.48 | 0.48 | 0.48 | 0.48 | 0.48 | 0.48 | 0.48 | 0.48 | 0.46 | 0.48 |
| conditioner | | | | | | | | | | |
| Fluorescent agent | 0.02 | 0.02 | 0.02 | 0.02 | 0.02 | 0.02 | 0.02 | 0.02 | 0.02 | 0.02 |
| Sum total | 100 | 100 | 100 | 100 | 100 | 100 | 100 | 100 | 100 | 100 |

[Components]
Ketone-based solvent: dimethyl carbonate, CAS No. 616-38-6
Carbon-based solvent: D-150 by Isu Chemical Co., Ltd.
First metal catalyst: cobalt octoate (CAS No. 13586-82-8)
Second metal catalyst: zirconium octoate (CAS No. 22464-99-9)
Defoamer: 3239 by AFCONA Chemicals
Surface conditioner: BYK-361 by BYK
Fluorescent agent: Benetex OB by MAYZO, Inc.

### Test Example 1: Evaluation of Stock Solution Stability

First, general properties and stock solution stabilities of the epoxy coating compositions prepared according to Examples 1 to 5 and Comparative Examples 1 to 5 were measured by evaluation methods corresponding to the following items. Results of measurement will be set forth in Table 3 below.

### [Evaluation Methods]

(1). Solids content: The solids contents of the epoxy coating compositions were measured based on ASTM D2697.
(2). Specific gravity: The specific gravities of the epoxy coating compositions were measured based on ASTM D1475.
(3). Viscosity: The viscosities of the epoxy coating compositions were measured based on KS M ISO 2884-2. Concretely, the viscosities of the epoxy coating compositions were measured by a Brookfield Viscometer (LV), and in this case, a spindle LV63 was used under measurement conditions of a speed of 100 rpm and a temperature of 25° C.
(4) Stock solution stability: The stock solution stabilities of the epoxy coating compositions were evaluated based on KS M 6030. Concretely, when a part or the entirety of an epoxy coating composition was gelled after preparation or when a part or the entirety of the epoxy coating composition was gelled after 24 hours of sealed storage at room temperature, the stock solution stability of the epoxy coating composition was determined as bad. When the epoxy coating composition was not gelled or when the viscosity of the epoxy coating composition was increased within 10% of the viscosity thereof after preparation, the stock solution stability of the epoxy coating composition was determined as good.

TABLE 3

| | Example | | | | | Comparative example | | | | |
|---|---|---|---|---|---|---|---|---|---|---|
| Category | 1 | 2 | 3 | 4 | 5 | 1 | 2 | 3 | 4 | 5 |
| Solids (wt %) | 39.8 | 39.4 | 39.7 | 29.8 | 29.9 | 40.1 | 39.7 | 39.8 | 39.6 | 39.7 |
| Specific | 1.05 | 1.05 | 1.05 | 1.07 | 1.07 | 1.05 | 1.05 | 1.05 | 1.05 | 1.03 |
| gravity | | | | | | | | | | |
| Viscosity | 104.5 | 109.3 | 111.2 | 37.7 | 38.2 | 115.2 | 121.6 | 128.4 | 133.5 | 140.8 |
| (cPs) | | | | | | | | | | |
| Stock solution | Good | Good | Good | Good | Good | Good | Good | Good | Bad | Bad |
| stability | | | | | | | | | | |

As shown in Table 3, the epoxy coating compositions according to Examples 1 to 5 and Comparative Examples 1 to 3 secured stock solution stability. Therefore, the epoxy coating compositions according to Examples of the present invention may be easy to be used in automated coating lines to which an automatic dispenser is applied.

On the other hand, the epoxy coating compositions according to Comparative Examples 4 and 5 did not secure stock solution stability.

### Test Example 2: Performance Test Evaluation

Performance tests were performed by evaluation methods depending on the following respective items, and test results are set forth in Table 4 below.

In the performance tests, the epoxy coating compositions according to Examples 1 to 5 and Comparative Examples 1 to 3, which secured stock solution stability, were coated on an IPC B25-A test board, which is a multipurpose one-sided test board formed of FR-4, to a thickness of 50 to 80 μm so as to manufacture specimens, and ACS-700 by IMPEC Enterprise Co., Ltd. in Korea was used as an automatic dispenser to manufacture the specimens.

The epoxy coating compositions according to Examples 1 to 3 and Comparative Examples 1 to 3 were applied in a spray valve manner, and the epoxy coating compositions according to Examples 4 and 5 were applied in a film valve manner.

The epoxy coating compositions according to Comparative Examples 4 and 5, which did not secure stock solution stability, were excluded from the performance test evaluation, because the corresponding epoxy coating compositions are not able to be applied to the board when the epoxy coating compositions are gelled.

After the manufactured specimens were cured at a temperature of 50 to 60° C. for 3 minutes in a hot air oven, and were cured at a room temperature of 25° C. and a relative humidity of 50% for 7 days, the following performance tests for the specimens were conducted.

### [Performance Test Evaluation]

(1). Appearance: The appearances of the specimens were checked using a 10× microscope, it was evaluated whether coating films are peeled off or floated from the surfaces of the specimens, and the specimens are transparent without wrinkles and foam bubbles, and test results were determined as good or bad.
(2). Withstand voltage: The withstand voltages of the specimens were evaluated under conditions of 0.1 to 1.5 kV/sec based on ATM D149, and test results were determined as pass or fail.
(3). Insulation resistance: The insulation resistances of the specimens were evaluated based on IEC 243, and test results were determined as pass or fail.
(4) Withstand voltage and insulation resistance: the HIOKI 3153 automatic insulation/withstanding tester by HIOKI in Japan was used as a withstand voltage and insulation resistance measurement device.
(5). Flexural properties: The flexural properties of the specimens were evaluated by bending coated copper specimens using a mandrel bending tester through our own test method, and test results were determined as pass when the coating film is not cracked or peeled, and were determined as fail when the coating film is damaged.
(6). Storage at high temperature: This test was evaluated based on JESD22-A102, and test results were determined as pass or fail.
(7). High temperature and high humidity test: The high temperature and high humidity test was evaluated based on the IPC-TM-650 test methods manual, quality abnormalities in insulation resistances of the specimens during the test, appearances, insulation resistances and withstand voltages of the specimens after the test, and the like were evaluated by performing the test at a temperature of 85° C. and a relative humidity of 85% for 500 hours, and test results were determined as pass or fail.
(8). Salt spray test: The salt spray test was evaluated based on ASTM B117, insulation resistances and withstand voltages of the specimens were evaluated after the specimens were washed with purified water after 96 hours and dried, and test results were determined as pass or fail.
(9). Water immersion test: In the water immersion test which was one of vehicle tests, after the specimens were immersed in purified water of a temperature of 25° C. such that the D patterns of the coated specimens (IPC-B-25A) were submerged in the purified water, and were left for 168 hours in the state in which 24 V was applied thereto, voltage application was stopped, the test boards were taken out of the purified water and dried, and then, insulation resistances and withstand voltages of the specimens were evaluated. Test results were determined as pass or fail.
(10). Coating film thickness at lead: The coating film thicknesses at leads of the specimens were evaluated through our own test method, the IC chip areas of the coated boards were cut out, cold mounting of the coated boards using a transparent two-component epoxy resin was carried out, and then, the thicknesses of the coating films at the leads of the respective boards were measured. Test results were determined as pass or fail.
(11). Functional operation test of mounting board (high temperature): In the functional operation test at a high temperature which was one of vehicle tests, after the above-described compositions were applied to 10 or more mounting boards using an automatic dispenser and dried, whether or not respective circuits of the mounting boards were properly operated at a high temperature of 80° C. was evaluated, and test results were determined as pass or fail.
(12). Functional operation test of mounting board (low temperature): In the functional operation test at a low temperature which was one of vehicle tests, after the above-described compositions were applied to 10 or more mounting boards using an automatic dispenser and dried, whether or not respective circuits of the mounting boards were properly operated at room temperature was evaluated, and test results were determined as pass or fail.

TABLE 4

| Test evaluation | | | Example | | | | | Comparative example | | |
|---|---|---|---|---|---|---|---|---|---|---|
| Board | Environment | Details | 1 | 2 | 3 | 4 | 5 | 1 | 2 | 3 |
| IPC B-25A | Room temp. | Appearance | Good | Good | Good | Good | Good | Good | Good | Good |
| test board | | Insulation | Pass | Pass | Pass | Pass | Pass | Pass | Pass | Pass |
| (multipurpose | | resistance | | | | | | | | |
| one-sided | | Withstand | Pass | Pass | Pass | Pass | Pass | Pass | Pass | Pass |
| test board) | | voltage | | | | | | | | |
| | | Flexural | Pass | Pass | Pass | Pass | Pass | Fail | Fail | Pass |
| | | properties | | | | | | | | |
| | Storage at | Appearance | Good | Good | Good | Good | Good | Good | Good | Bad |
| | high temp. | Insulation | Pass | Pass | Pass | Pass | Pass | Pass | Pass | Pass |
| | | resistance | | | | | | | | |
| | | Withstand | Pass | Pass | Pass | Pass | Pass | Pass | Pass | Pass |
| | | voltage | | | | | | | | |
| | | Flexural | Pass | Pass | Pass | Pass | Pass | Fail | Fail | Pass |
| | | properties | | | | | | | | |
| | Thermal | Appearance | Good | Good | Good | Good | Good | Good | Bad | Bad |
| | shock | Insulation | Pass | Pass | Pass | Pass | Pass | Pass | Pass | Pass |
| | | resistance | | | | | | | | |
| | | Withstand | Pass | Pass | Pass | Pass | Pass | Pass | Pass | Pass |
| | | voltage | | | | | | | | |
| | High temp. | Appearance | Good | Good | Good | Good | Good | Good | Good | Bad |
| | and high | Insulation | Pass | Pass | Pass | Pass | Pass | Pass | Fail | Fail |
| | humidity | resistance | | | | | | | | |
| | | during test | | | | | | | | |
| | | Insulation | Pass | Pass | Pass | Pass | Pass | Pass | Pass | Pass |
| | | resistance | | | | | | | | |
| | | after test | | | | | | | | |
| | | Withstand | Pass | Pass | Pass | Pass | Pass | Pass | Fail | Fail |
| | | voltage | | | | | | | | |
| | Salt spray | Insulation | Pass | Pass | Pass | Pass | Pass | Pass | Pass | Pass |
| | | resistance | | | | | | | | |
| | | Withstand | Pass | Pass | Pass | Pass | Pass | Pass | Pass | Fail |
| | | voltage | | | | | | | | |
| | Immersion | Insulation | Pass | Pass | Pass | Pass | Pass | Pass | Pass | Pass |
| | in purified | resistance | | | | | | | | |
| | water | Withstand | Pass | Pass | Pass | Pass | Pass | Pass | Pass | Fail |
| | | voltage | | | | | | | | |
| Mounting | Room temp. | Coating | Pass | Pass | Pass | Pass | Pass | Fail | Pass | Fail |
| board | | film | | | | | | | | |
| | | thickness | | | | | | | | |
| | | at lead | | | | | | | | |
| | High temp. | Functional | Pass | Pass | Pass | Pass | Pass | Fail | Fail | Fail |
| | Room temp. | operation | Pass | Pass | Pass | Pass | Pass | Pass | Pass | Fail |
| | | test of | | | | | | | | |
| | | mounting | | | | | | | | |
| | | board | | | | | | | | |

As shown in Table 4, the epoxy coating compositions according to Examples of the present invention have excellent physiochemical characteristics and good electrical characteristics under various external environment conditions, compared to the epoxy coating compositions according to Comparative Examples.

Further, the epoxy coating compositions according to Examples of the present invention satisfy coating film thickness standards at a lead, i.e., a kind of vertical application which is a requirement for uniformity of application.

Moreover, the epoxy coating compositions according to Examples of the present invention may employ a modification of an epoxy resin which is similar to a material for electronic circuit boards contrary to conventional technology so as to have excellent thermal resistance and adhesiveness, may employ a dual method using both drying and oxidative curing so as to enable curing at room temperature, and may have an increased solids content so as to form a uniform coating film on an electronic circuit board.

Therefore, an epoxy coating composition for protection of electronic circuit boards prepared by the preparation method according to various exemplary embodiments of the present invention not only satisfies physiochemical characteristics and electrical characteristics which are essential to secure reliability of a vehicle, but also satisfies core properties on a mounting board, such as resistance to high-temperature and high-humidity and stability upon thermal shock.

Further, the epoxy coating composition according to various exemplary embodiments of the present invention may satisfy regulations on harmful substances, such as benzene, toluene and xylene (BTX) which are volatile organic compounds (VOCs), and aldehyde, which are eco-friendly requirements.

Moreover, the epoxy coating composition according to various exemplary embodiments of the present invention may have a high solids content compared to the conventional solvent-type conformal coating composition, and may employ an eco-friendly and low-odor solvent and thus remarkably reduce odor and the amount of substances, such as VOCs, generated during a process of forming a coating layer.

As is apparent from the above description, an epoxy coating composition for protection of electronic circuit boards according to the present invention may be easily applied to the conventional coating operation and the coating lines of the automated continuous process, may have low odor emission, may be a one-component type to be uniformly applied to an electronic circuit board, and may form a transparent coating film through drying at room temperature and oxidative curing, thereby being capable of protecting the electronic circuit board from external environmental changes, such as moisture and vibration, and foreign substances, such as dust and contaminants, and thus effectively improving the reliability and durability of the electronic circuit board.

Further, the epoxy coating composition according to the present invention may reduce generation of harmful substances, such as VOCs, and may have low odor emission, compared to conventional coating compositions.

The invention has been described in detail with reference to exemplary embodiments thereof. However, it will be appreciated by those skilled in the art that changes may be made in these embodiments without departing from the principles and spirit of the invention, the scope of which is defined in the appended claims and their equivalents.

What is claimed is:

1. An epoxy coating composition for protection of electronic circuit boards, comprising:
an amount of about 35 to 70 wt % of a modified epoxy resin comprising a fatty acid-acrylic epoxy resin;
an amount of about 30 to 65 wt % of a first solvent;
an amount of about 0.1 to 1.2 wt % of a metal catalyst;
an amount of about 0.05 to 0.45 wt % of a defoamer; and
an amount of about 0.1 to 0.5 wt % of a surface conditioner,
based on the total weight of the epoxy coating composition,
wherein the fatty acid-acrylic epoxy resin is prepared by polymerizing a reactant that is obtained by a reaction between an epoxy resin mixture and an unsaturated fatty acid with an acrylic resin.

2. The epoxy coating composition of claim 1, wherein the reactant is obtained by a dehydration condensation reaction between 100 parts by weight of the epoxy resin mixture and 50 to 80 parts by weight of the unsaturated fatty acid.

3. The epoxy coating composition of claim 1, wherein the epoxy resin mixture comprises, based on a total weight thereof:
an amount of about 60 to 80 wt % of a first epoxy resin; and
an amount of about 20 to 40 wt % of a second epoxy resin,
based on the total weight of the epoxy resin mixture,
wherein the first epoxy resin has a softening point of about 60 to 85° C., and the second epoxy resin has a softening point of about 110 to 140° C.

4. The epoxy coating composition of claim 1, wherein:
the unsaturated fatty acid comprises one or more selected from the group consisting of a castor oil-derived fatty acid, a soybean oil-derived fatty acid, and a rapeseed oil-derived fatty acid; and
the unsaturated fatty acid has an iodine value of about 100 to 150 mgKOH/g.

5. The epoxy coating composition of claim 1, wherein the fatty acid-acrylic epoxy resin is obtained by a reaction between 100 parts by weight of the reactant and about 10 to 30 parts by weight of the acrylic resin.

6. The epoxy coating composition of claim 1, wherein a polymerization catalyst is used to the fatty acid-acrylic epoxy resin is prepare the reactant that is polymerized to prepare the fatty acid-acrylic epoxy resin.

7. The epoxy coating composition of claim 1, wherein the acrylic resin comprises one or more selected from the group consisting of methyl methacrylate, methyl acrylate, ethyl acrylate, and ethylhexyl acrylate.

8. The epoxy coating composition of claim 1, wherein the modified epoxy resin further comprises a second solvent comprising an alcohol glycol ether-based solvent, a ketone-based solvent, or a combination thereof.

9. The epoxy coating composition of claim 8, wherein:
the alcohol glycol ether-based solvent comprises one or more selected from the group consisting of butyl carbitol, propylene glycol monomethyl ether, and propylene glycol monoethyl ether; and
the ketone-based solvent comprises one or more selected from the group consisting of methyl ethyl ketone, methyl isobutyl ketone, acetone, and dimethyl carbonate.

10. The epoxy coating composition of claim 1, wherein the modified epoxy resin has a Gardner viscosity of Z to Z2, an acid value of less than about 8 mgKOH/g, an iodine value of about 20 to 50 mgKOH/g, and a solids content of about 30 to 70 wt % based on the total weight of the modified epoxy resin.

11. The epoxy coating composition of claim 1, wherein the first solvent comprises:
an amount of about 30 to 60 wt % of a ketone-based solvent; and
an amount of about 0 to 5 wt % of a carbon-based solvent,
based on the total weight of the epoxy coating composition.

12. The epoxy coating composition of claim 11, wherein:
the ketone-based solvent comprises one or more selected from the group consisting of methyl ethyl ketone, methyl isobutyl ketone, acetone, and dimethyl carbonate; and
the carbon-based solvent comprises naphthene-based hydrocarbon, paraffin-based hydrocarbon, or a combination thereof.

13. The epoxy coating composition of claim 1, wherein the metal catalyst comprises one or more selected from the group consisting of cobalt octoate, calcium octoate, and zirconium octoate.

14. The epoxy coating composition of claim 1, wherein the defoamer comprises a silicone-based defoamer, a silicone-free defoamer, or a combination thereof, wherein:
the silicone-based defoamer comprises one or more selected from the group consisting of polydimethylsiloxane, polyether-modified polydimethylsiloxane, and fluorine-modified polydimethylsiloxane; and
the silicone-free defoamer comprises polyacrylates, polyalkylene ethers, or combinations thereof.

15. The epoxy coating composition of claim 1, wherein the surface conditioner comprises a polyacrylate-based surface conditioner, a polyalkylene ether-based surface conditioner, or a combination thereof.

16. The epoxy coating composition of claim 1, further comprising an amount of about 0.01 to 0.1 wt % of a fluorescent agent based on the total weight of the epoxy coating composition.

17. An electronic circuit board comprising:
a board; and
a coating layer located on the board and comprising an epoxy coating composition,
wherein the epoxy coating composition comprises:
an amount of about 35 to 70 wt % of a modified epoxy resin comprising a fatty acid-acrylic epoxy resin;
an amount of about 30 to 65 wt % of a first solvent;
an amount of about 0.1 to 1.2 wt % of a metal catalyst;
an amount of about 0.05 to 0.45 wt % of a defoamer; and
an amount of about 0.1 to 0.5 wt % of a surface conditioner,
the wt % is based on the total weight of the epoxy coating composition,
wherein the fatty acid-acrylic epoxy resin is prepared by polymerizing a reactant that is obtained by a reaction between an epoxy resin mixture and an unsaturated fatty acid with an acrylic resin using a polymerization catalyst.

18. A method of preparing an epoxy coating composition for protection of electronic circuit boards, comprising:
preparing a reactant obtained by a dehydration condensation reaction between an epoxy resin mixture and an unsaturated fatty acid;
preparing a fatty acid-acrylic modified epoxy resin by polymerizing the reactant with an acrylic resin using a polymerization catalyst;
preparing a modified epoxy resin by diluting the fatty acid-acrylic modified epoxy resin with a second solvent; and
reacting an amount of about 35 to 70 wt % of the modified epoxy resin, an amount of about 30 to 65 wt % of a first solvent, an amount of about 0.1 to 1.2 wt % of a metal catalyst, an amount of about 0.05 to 0.45 wt % of a defoamer, and an amount of about 0.1 to 0.5 wt % of a surface conditioner, based on the total weight of the epoxy coating composition and then stirring the same.

19. The method of claim 18, wherein:
the fatty acid-acrylic epoxy resin is obtained by a reaction between 100 parts by weight of the reactant and about 10 to 30 parts by weight of the acrylic resin; and
the reactant is obtained by a dehydration condensation reaction between 100 parts by weight of the epoxy resin mixture and about 50 to 80 parts by weight of the unsaturated fatty acid.

20. The method of claim 18, wherein:
the fatty acid-acrylic epoxy resin comprises a first epoxy resin having a softening point of about 60 to 85° C. and a second epoxy resin having a softening point of about 110 to 140° C.;
the unsaturated fatty acid comprises one or more selected from the group consisting of a castor oil-derived fatty acid, a soybean oil-derived fatty acid, and a rapeseed oil-derived fatty acid;
the acrylic resin comprises one or more selected from the group consisting of methyl methacrylate, methyl acrylate, ethyl acrylate, and ethylhexyl acrylate;
the polymerization catalyst comprises bis(1,1-dimethyl) peroxide (di-tert-butyl peroxide);
the first solvent comprises a ketone-based solvent, a carbon-based solvent, or a combination thereof; and
the second solvent comprises an alcohol glycol ether-based solvent, a ketone-based solvent, or a combination thereof.
